(19) United States
(12) Patent Application Publication
(10) Pub. No.: US 2015/0001527 A1
(43) Pub. Date: Jan. 1, 2015

(54) LIGHT EMITTING DISPLAY HAVING LIGHT SENSORS

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/221,237

(22) Filed: Mar. 20, 2014

(30) Foreign Application Priority Data
Jun. 28, 2013 (TW) 102123136

(51) Int. Cl. H01L 25/16; H01L 27/12; H01L 27/15; H01L 31/12

(52) U.S. Cl. CPC H01L 25/167; H01L 31/12; H01L 27/1225; H01L 27/156
USPC 257/43

(57) ABSTRACT

A light emitting display includes a light emitting diode formed on a first substrate, a thin film transistor formed on a second substrate, and a light sensing unit located at a lateral side of the thin film transistor. The first substrate and the second substrate are arranged face-to-face and are spaced from each other. And the thin film transistor and the light emitting diode are formed between the first and second substrates. The light sensing unit is located at a light path of the light emitting diode to detect an intensity of light from the light emitting diode, and the thin film transistor is offset from the light path of the light emitting diode and is electrically connected with the light sensing unit.

### BACKGROUND

1. Technical Field

This disclosure generally relates to light emitting displays, and particularly to a light emitting display including oxide semiconductors functioning as light sensors.

2. Description of Related Art

A typical active matrix organic light emitting display (AMOLED) includes a plurality of organic light emitting elements as light sources. However, in manufacturing processes of the active matrix organic light emitting display, the organic light emitting materials are prone to be affected by environmental factors, such as moisture, which causes the organic materials to be deteriorated. Therefore, the manufacturing process of the active matrix organic light display needs to be performed in a vacuum environment to avoid the deterioration of the organic materials, resulting in a complicated manufacturing process of the active matrix organic light display. In addition, the different colors of organic light emitting materials of the matrix organic light emitting display each have a different service life and luminous efficiency, causing a color cast of the active matrix organic light display.

What is needed, therefore, is a light emitting display having at least one light sensor which can overcome the above-described shortcoming.

### BRIEF DESCRIPTION OF THE DRAWINGS

FIG. 1 is a cross-sectional view of a light emitting display having a light sensing function according to a first embodiment of the present disclosure.

FIG. 2 is a cross-sectional view of a light emitting display having a light sensing function according to a second embodiment of the present disclosure.

FIG. 3 is a cross-sectional view of a light emitting display having a light sensing function according to a third embodiment of the present disclosure.

FIG. 4 is a cross-sectional view of a light emitting display having a light sensing function according to a fourth embodiment of the present disclosure.

### DETAILED DESCRIPTION

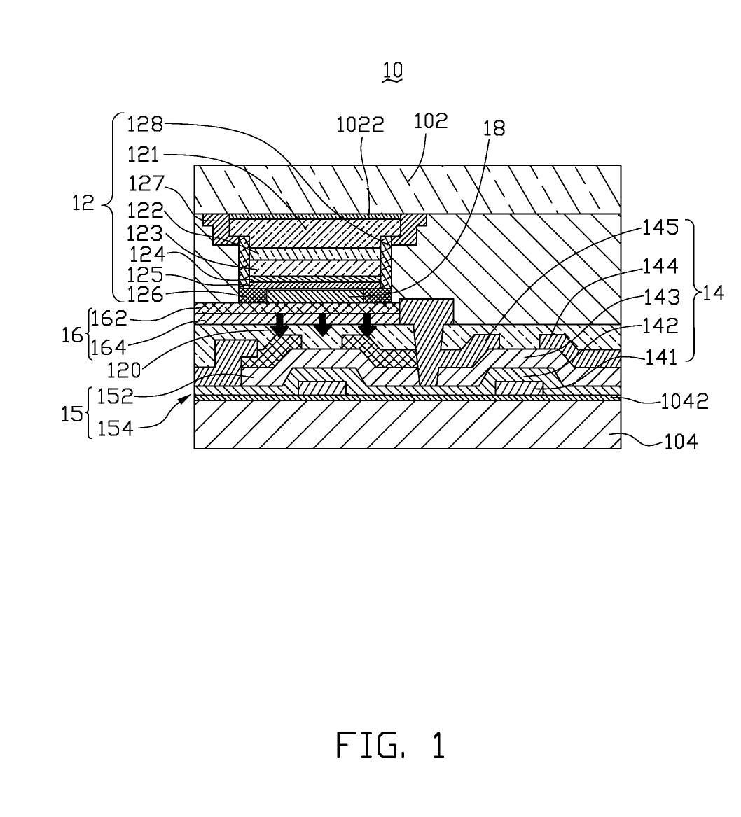

Referring to FIG. 1, a light emitting display 10 having a light sensing function in accordance with a first embodiment of the present disclosure is provided.

The light emitting display 10 includes a light emitting diode 12, a thin film transistor 14, a light sensing unit 15 and a connecting layer 16. The light emitting diode 12 is formed on a first substrate 102. The thin film transistor 14 and the light sensing unit 15 are formed on a second substrate 104, and electrically connect with each other.

The first substrate 102 and the second substrate 104 are arranged face-to-face. The first substrate 102 is spaced from the second substrate 104. The first substrate 102 and the second substrate 104 are made of sapphire, silicon, silicon on glass, glass, AlO, GaN, ZnO, plastic or a flexible material. In this embodiment, the first substrate 102 is made of sapphire or silicon on glass. The second substrate 104 is made of glass. The light emitting diode 12 is a nitride light emitting diode.

A first buffer layer 1022 is formed on an inner surface of the first substrate 102, and the light emitting diode 12 is formed on the first buffer layer 1022. A second buffer layer 1042 is formed on an inner surface of the second substrate 104, and the thin film transistor 14 is formed on the second buffer layer 1042. The first buffer layer 1022 and the second buffer layer 1042 are electrically-insulating buffer layers. The first buffer layer 1022 is made of AlGaInN, SiC, ZnO, or a combination thereof The second buffer layer 1042 is made of SiOₓ, SiNₓ, SiON, HfOₓ, AlOₓ, TaOₓ, BaSrTiOₓ, or a combination thereof Preferably, the first buffer layer 1022 and the second buffer layer 1042 are made of low temperature CaN or SiOₓ.

The light emitting diode 12 is located at a lateral side of the thin film transistor 14 and includes an n-type semiconductor layer 121, a light emitting layer 122, a p-type semiconductor layer 123, a contact layer 124 and a current spreading layer 125 sequentially formed on the first buffer layer 1022 along a top to bottom direction. A p-type electrode 126 is formed on the current spreading layer 125. An n-type electrode 127 is formed at a lateral side of the n-type semiconductor layer 121. An insulation layer 128 is formed between the n-type electrode 127 and the p-type electrode 128. The insulation layer 128 insulates the n-type electrode 127 from the p-type electrode 128, and the n-type electrode 127 contacts with a top end of the insulation layer 128, the p-type electrode 126 contacts with a bottom end of the insulation layer 128.

The contact layer 124 is an ohmic contact layer. The current spreading layer 125 is a low contact resistant layer and can be a doped inversion layer, which is used to increase the luminous efficiency of the light emitting diode 12. The light emitting layer 122 is a single quantum well or multiple quantum wells. The light emitting layer 122 is made of AlₓGa_{y}In_{(1-x-y)}N, 0≦x≦1, 0≦y≦1.

The light emitting diode 12 can emit UV light, blue light, green light or other visible light. Preferably, the wavelength of light 120 emitted by the light emitting diode 12 is ranged from 300 nm-550 nm.

The thin film transistor 14 includes a gate electrode 141, a source electrode 144 and a drain electrode 145. The gate electrode 141 is formed on the second buffer layer 1042. An insulation layer 142 is formed on the gate electrode 141, and covers the gate electrode 141. An active layer 143 is formed on the insulation layer 142. The source electrode 144 and the drain electrode 145 are formed on the active layer 143.

The insulation layer 142 is made of SiOₓ, SiNₓ, SiON, HfOₓ, AlOₓ, TaOₓ, or BaSrTiOₓ. The active layer 143 is a photosensitive semiconductor active layer. The photosensitive semiconductor active layer is an oxide semiconductor. The active layer 143 includes at least one metal, such as In, Ca, Al, Zn, Cd, Ga, Mo, Sn, Hf, Cu, Ti, Ba, or Zr. The active layer 143 is made of InGaZnO, InZnHfO, InZnZrO, InZnSnO, InZnO, AlInZnO, ZnO, or AlInZnO. The source electrode 144 and the drain electrode 145 are metal electrodes, or oxide semiconductor electrodes.

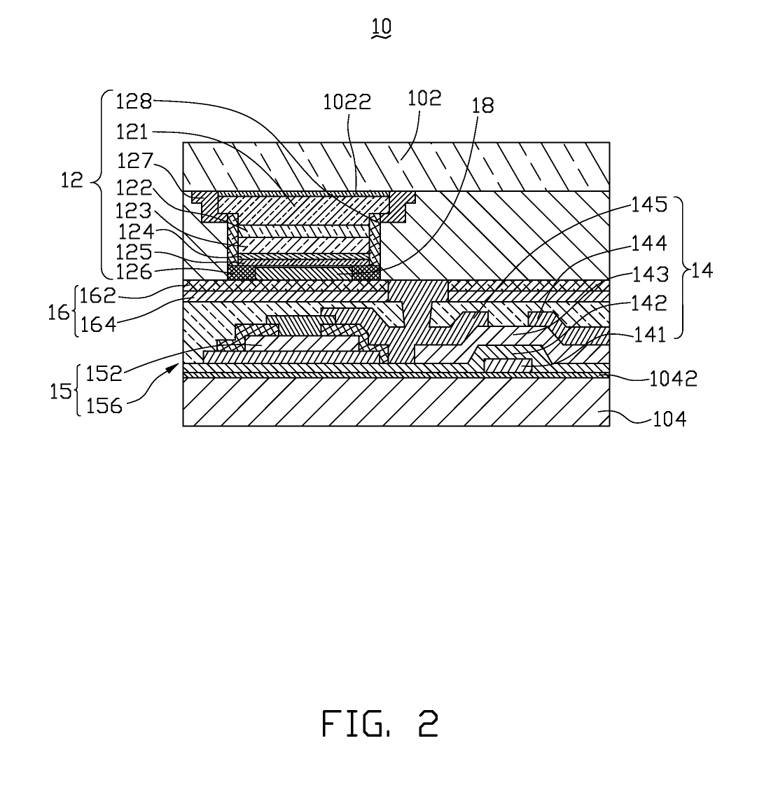

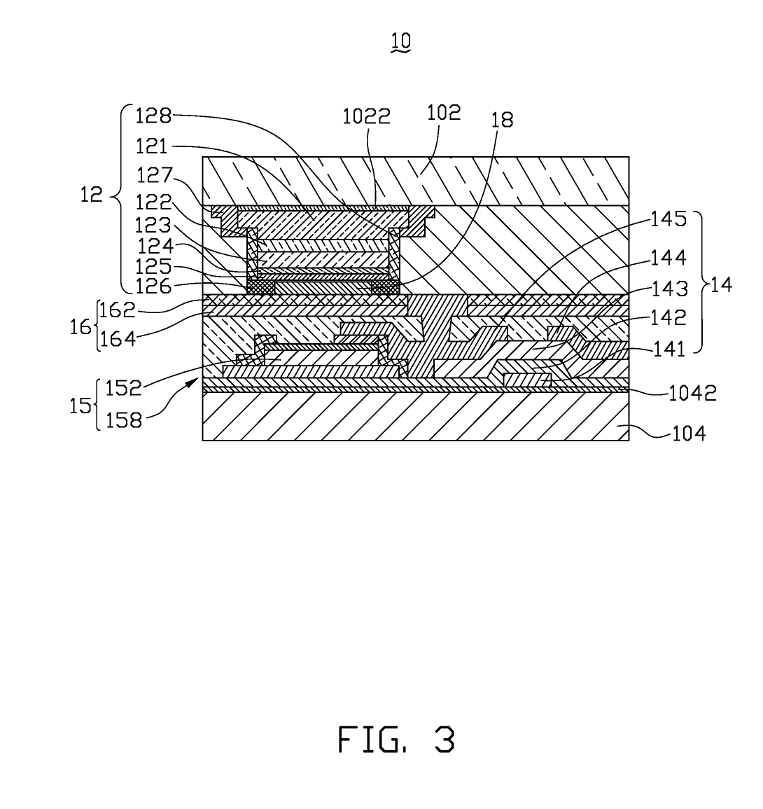

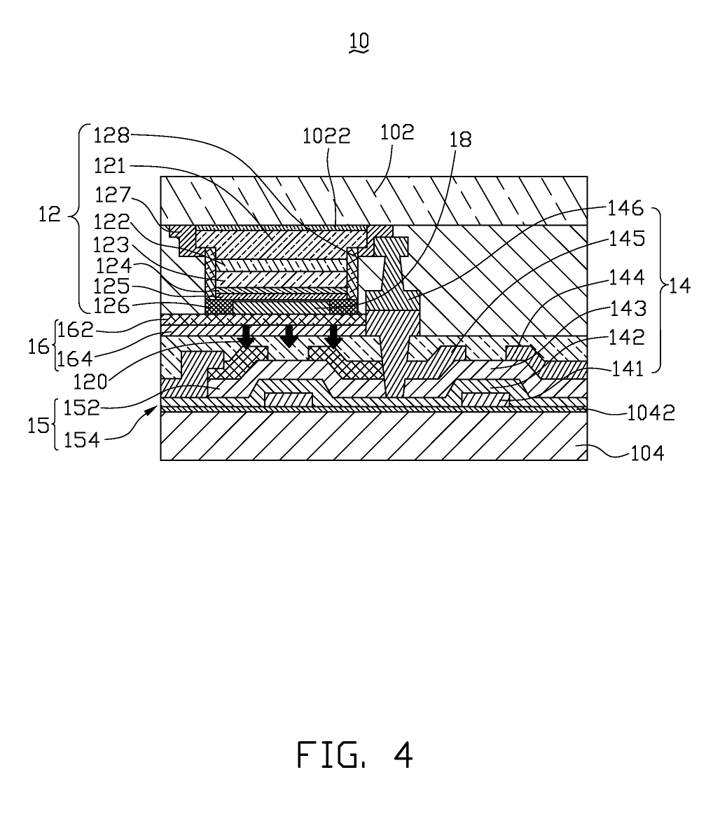

The light sensing unit 15 is formed at a lateral side of the thin film transistor 14. The light sensing unit 15 includes an oxide semiconductor layer 152. The oxide semiconductor layer 152 is an active layer. The oxide semiconductor layer 152 comprises at least one metal, such as In, Ca, Al, Zn, Cd, Ga, Mo, Sn, Hf, Cu, Ti, Ba, or Zr. The oxide semiconductor layer 152 is made of InGaZnO, InZnHfO, InZnZrO, InZnSnO, InZnO, AlInZnO, ZnO, or AlInZnO. The light sensing unit 15 further includes a photo transistor 154 (FIGS. 1, 4), a schottky barrier photodiode 156 (FIG. 2) or a PIN photodiode 158 (FIG. 3).

The connecting layer 16 is an electrically conductive connecting layer. The connecting layer 16 electrically connects the light emitting diode 12 with the thin film transistor 14. The connecting layer 16 is made of metals, conductive oxides, conductive glue, solder carbon nano tubes or a graphene material. That is, the connecting layer 16 can be a multilayer structure. The connecting layer 16 includes a metal layer 162 and a transparent conductive oxide layer 164. The metal layer 162 is made of In, Ga, Al, Zn, Cr, Ni, Mo, Sn, Ag, Au, Cu, Ti, Bi, Co, or an ally thereof. The transparent conductive oxide layer 164 is made of InSnO, ZnSnO, InZnO, AlZnO, InZnSnO, InGaZnO, InZnHfO, or InZnZrO. Alternatively, the connecting layer 16 is made of silver glue, SnBi, SnBiCu, SnBiTe, SnBiSe, BiSbTe, BiTeSe, or SnAgCu.

The light emitting diode 12 and the thin film transistor 14 are located between the first substrate 102 and the second substrate 104. In this embodiment, the first substrate 102 is located above the second substrate 104, and faces the second substrate 104, the light emitting diode 12 is located at a left portion of the first substrate 102, and the thin film transistor 14 is located at a right portion of the second substrate 104. The connecting layer 16 electrically connects the p-type electrode 126 of the light emitting diode 12 to the drain electrode 145 of the thin film transistor 14 to make the light emitting diode 12 electrically connect with the thin film transistor 14. Alternatively, the connecting layer 16 may electrically connect the p-type electrode 126 of the light emitting diode 12 to the source electrode 144 of the thin film transistor 14.

The light emitting diode 12 and the thin film transistor 14 are offset from each other, whereby the thin film transistor 14 is deviated from a light path of the light emitting diode 12 as indicated by arrows 120 in FIG. 1. The light sensing unit 15 is located below and aligned with the light emitting diode 12 along a thickness direction of the light emitting display 10. In other words, the light emitting diode 12 does not cover the thin film transistor 14 along the thickness direction of the light emitting display 10. The light sensing unit 15 is located at the light path of the light emitting diode 12, and the thin film transistor 14 deviates from the light path of the light emitting diode 12. In this embodiment as shown in FIG. 1, the light sensing unit 15 includes the phototransistor 154. The oxide semiconductor layer 152 of the light sensing unit 15 is located at the light path of the light emitting diode 12 to sense the light intensity of light from the light emitting diode 12, and transforms the optical signals of the light into electric signals. The electric signals are transmitted to drive the thin film transistor 14 to control or compensate the light intensity of the light emitting diode 12 by a way of electrical feedback. The thin film transistor 14 is offset from the light emitting diode 12, such that, the light emitted from the light emitting diode 12 is avoided from directly radiating the active layer 143 of the thin film transistor 14, whereby a possibility of change of electrical characteristics of the active layer 143 due to illumination of the light emitted from the light emitting diode 12 thereon is significantly reduced.

The thin film transistor 14 includes a metallic electrode. The metallic electrode of the thin film transistor 14 blocks the light emitted from light emitting diode 12 to radiate the active layer 143 of the thin film transistor 14. The metallic electrode is formed on at least one of the source electrode 144 and the drain electrode 145. As shown in FIG. 4, a metal column 146 is formed on the drain electrode 145. Alternatively, the metal column 146 can be formed on the source electrode 144.

The metal column 146 electrically connects the source electrode 144 or the drain electrode 145 to the n-type electrode 127 of the light emitting diode 12. In this embodiment, the metal column 146 functions as the metallic electrode mentioned above and blocks the light emitted from the light emitting diode 12 from radiating the active layer 143 of the thin film transistor 14.

The light emitting display 10 further includes a phosphor layer 18. The phosphor layer 18 is provided inside the light emitting display 10, and is located at a light path of the light emitting diode 12. In this embodiment, the phosphor layer 18 is located between the current spreading layer 125 and the connecting layer 16, and is also located between the p-type electrodes 126 at lateral sides of the current spreading layer 125. The phosphor layer 18 absorbs primary light emitted from the light emitting layer 122 of the light emitting diode 12, and converts the primary light to secondary light with another wavelength, such as red light, green light, blue light, yellow light, or yellow-green light, which mixes with the remaining primary light to generate a resultant light having a light path as indicated by the arrows 120 of FIG. 1, wherein the resultant light can be white light.

Referring to FIG. 2, in the second embodiment, the light sensing unit 15 includes the schottky barrier photodiode 156. The light sensing unit 15 is located at a lateral side of the thin film transistor 14, and electrically connects with the thin film transistor 14. The light sensing unit 15 is located at the light path of the light emitting diode 12. The oxide semiconductor layer 152 of the light sensing unit 15 senses the light intensity of the light emitted from the light emitting diode 12, and drives the thin film transistor 14 to control or compensate the light intensity of the light emitting diode 12.

Referring to FIG. 3, the light sensing unit 15 includes the PIN photodiode 158. The PIN photodiode 158 is located at a lateral side of the thin film transistor 14, and electrically connects with the thin film transistor 14. The PIN photodiode 158 is located at the light path of the light emitting diode 12. The PIN photodiode 158 includes an oxide semiconductor layer 152. The oxide semiconductor layer 152 senses the light intensity of the light emitted from the light emitting diode 12, and drives the thin film transistor 14 to control or compensate the light intensity of the light emitting diode 12.

According to the light emitting display 10 of this disclosure, because of the material properties of the light emitting diode 12, the problem of degradation of organic materials in the manufacturing process of light emitting display 10 can be effectively solved. In addition, because the light sensing unit 15 is used to sense the light intensity of the light emitting diode 12 and drives the thin film transistor 14 to control and compensate the light intensity of the light emitting diode 12, the problem of color cast is effectively solved.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting display, comprising:
a light emitting diode formed on a first substrate;
a thin film transistor formed on a second substrate, the first substrate and the second substrate being arranged face-to-face and spaced from each other, and the thin film transistor and the light emitting diode being formed between the first and second substrates; and
a light sensing unit located at a lateral side of the thin film transistor and electrically connecting with the thin film transistor, the light sensing unit being located at a light path of the light emitting diode to sense intensity of the light from the light emitting diode, and the thin film transistor being deviated from the light path of the light emitting diode.

2. The light emitting display of claim 1, wherein the first substrate and the second substrate are made of sapphire, silicon, silicon on glass, glass, GaN, ZnO, plastic or a flexible material.

3. The light emitting display of claim 2, wherein the first substrate is made of sapphire or silicon on glass, and the second substrate is made of glass.

4. The light emitting display of claim 1, wherein a first buffer layer is formed on the first substrate and the light emitting diode is formed on the first buffer layer.

5. The light emitting display of claim 1, wherein a second buffer layer is formed on the second substrate and the thin film transistor is formed on the second substrate.

6. The light emitting display of claim 1, wherein a first buffer layer is formed on the first substrate, the light emitting diode is formed on the first substrate, a second buffer layer is formed on the second substrate, the thin film transistor is formed on the second substrate, one of the first buffer layer and the second buffer layer is AlGaInN or SiOₓ.

7. The light emitting display of claim 1, wherein the light emitting diode is a nitride light emitting diode, the light emitting diode comprises an n-type semiconductor layer, a light emitting layer, a p-type semiconductor layer, a contact layer and a current spreading layer sequentially formed on the first substrate along a top to bottom direction, a p-type electrode is formed on the current spreading layer, an n-type electrode is formed at a lateral side of the n-type semiconductor layer.

8. The light emitting display of claim 7, wherein the light emitting layer is made of AlₓGa_{y}In_{(1-x-y)}N, 0x≦1, 0≦y≦1.

9. The light emitting display of claim 7, wherein the light emitting diode emits light with a wavelength of 300 nm-550 nm.

10. The light emitting display of claim 1, wherein the thin film transistor comprises a gate electrode, a source electrode and a drain electrode, the gate electrode is formed on the second substrate, an insulation layer is formed on the gate electrode and covers the gate electrode, an active layer is formed on the insulation layer, and the source electrode and the drain electrode are formed on the active layer.

11. The light emitting display of claim 10, wherein the insulation layer is made of SiOₓ, SiNₓ, SiON, HfOₓ, AlOₓ, TaOₓ, or BaSrTiOₓ.

12. The light emitting display of claim 10, wherein the active layer is a photosensitive semiconductor active layer.

13. The light emitting display of claim 12, wherein the active layer is made of InGaZnO, InZnHfO, InZnZrO, InZnSnO, InZnO, AlInZnO, ZnO, or AlInZnO.

14. The light emitting display of claim 12, wherein the active layer comprises at least one metal of In, Ca, Al, Zn, Cd, Ga, Mo, Sn, Hf, Cu, Ti, Ba, or Zr.

15. The light emitting display of claim 1, wherein the thin film transistor comprises a metal electrode and the metal electrode is formed on at least one of the source electrode and the drain electrode.

16. The light emitting display of claim 15, wherein one of the source electrode and the drain electrode comprises a metal column and the metal column electrically connects with the light emitting diode.

17. The light emitting display of claim 16, wherein the metal column electrically connects the n-type electrode of the light emitting diode adjacent to the thin film transistor.

18. The light emitting display of claim 1, wherein the light sensing unit is a phototransistor, a schottky barrier photodiode, or a PIN photodiode.

19. The light emitting display of claim 1, wherein the light sensing unit comprises an oxide semiconductor layer, and the oxide semiconductor layer is an active layer.

20. The light emitting display of claim 19, wherein the oxide semiconductor layer is made of InGaZnO, InZnHfO, InZnZrO, InZnSnO, InZnO, AlInZnO, ZnO, or AlInZnO.

21. The light emitting display of claim 19, wherein the oxide semiconductor layer contains at least one metal and the metal is selected from In, Ca, Al, Zn, Cd, Ga, Mo, Sn, Hf, Cu, Ti, Ba, or Zr.

22. The light emitting display of claim 1 further comprising a connecting layer electrically connecting the light emitting diode and the thin film transistor, wherein the connecting layer is made of metal, conductive oxides, conductive glue, solder, carbon nano tubes, graphene, or a combination thereof.

23. The light emitting display of claim 1 further comprising a connecting layer electrically connecting the light emitting diode and the thin film transistor, wherein the connecting layer is a multilayer structure comprising a metal layer and a transparent conductive oxide layer.

24. The light emitting display of claim 23, wherein the metal layer is made of In, Ga, Al, Zn, Cr, Ni, Mo, Sn, Ag, Au, Cu, Ti, Bi, Co, or an ally thereof.

25. The light emitting display of claim 23, wherein the transparent conductive oxide layer is made of InSnO, ZnSnO, InZnO, AlZnO, InZnSnO, InGaZnO, InZnHfO, or InZnZrO.

26. The light emitting display of claim 1 further comprising a phosphor layer, wherein the phosphor layer absorbs light emitted from a light emitting layer of the light emitting diode and converts the light to another light with another wavelength.
